(19) United States
(12) Patent Application Publication
(10) Pub. No.: US 2014/0202922 A1
(43) Pub. Date: Jul. 24, 2014

(54) CARRIER FOR RECEIVING ONE OR MORE ELECTRONIC MODULES

(71) Applicant: FUJITSU COMPONENT LIMITED, Tokyo (JP)

(72) Inventor: Tatsushi Shibuya, Tokyo (JP)

(73) Assignee: FUJITSU COMPONENT LIMITED, Tokyo (JP)

(21) Appl. No.: 14/155,430

(22) Filed: Jan. 15, 2014

(30) Foreign Application Priority Data
Jan. 18, 2013 (JP) 2013-007848

(51) Int. Cl. H01L 21/673

(52) U.S. Cl. CPC H01L 21/67333
USPC 206/722

(57) ABSTRACT

A carrier for receiving one or more electronic modules includes a carrier member having one or more receiving receptacles, each of the one or more receiving receptacles being shaped to match an outline shape of an electronic module having at least one corner thereof chamfered.

### BACKGROUND OF THE INVENTION

1. Field of the Invention

The disclosures herein relate to a carrier for receiving electronic modules and an electronic module for placement in the carrier.

2. Description of the Related Art

An electronic module to be mounted on an electronic substrate may be supplied on a reel tape or component carrier, which is then set in a chip mounting apparatus or the like to mount the electronic module on an electronic substrate or the like. The orientation of electronic modules on the reel tape or component carrier are aligned in a predetermined direction at the time of preparing the reel tape or component carrier on which the electronic modules are placed.

An automatic check of the orientation of electronic modules on the reel tape or the like may require a video camera or the like that takes images of the electronic modules on the reel tape or component carrier prior to mounting, or takes images of the electronic modules mounted on an electronic substrate prior to shipment or delivery. Image processing may be performed to monitor the orientation of the electronic modules.

Part of a semiconductor component may be chamfered to provide easier positioning of the semiconductor component (see Japanese Patent Application Publication No. 2007-194667, and Japanese Patent Application Publication No. 2002-374098, Japanese Patent Application Publication No. 2008-34731, for example).

Electronic components supplied on a reel tape or component carrier cannot be correctly mounted on an electronic substrate by use of a chip mounting apparatus when the orientations of the electronic components vary from component to component at the time of placing the electronic components on the reel tape or component carrier.

The use of a camera to check the orientations of components requires an expensive monitor system to be installed.

Electronic components disclosed in the above-noted patent documents may allow the orientation of the electronic components to be checked. However, such an arrangement cannot be applied to electronic modules that are supplied on a reel tape or component carrier.

Accordingly, it may be desired to provide a carrier for receiving electronic modules that allows the electronic modules to be surface-mounted in the correct orientation.

### SUMMARY OF THE INVENTION

It is a general object of the present invention to provide a carrier and an electronic module that substantially obviate one or more problems caused by the limitations and disadvantages of the related art.

According to an embodiment, a carrier for receiving one or more electronic modules includes a carrier member having one or more receiving receptacles, each of the one or more receiving receptacles being shaped to match an outline shape of an electronic module having at least one corner thereof chamfered.

According to an embodiment, an electronic module of a rectangular shape has four corners, at least one but not all of which is chamfered.

According to an embodiment, a carrier for receiving one or more electronic modules includes a carrier member having one or more receiving receptacles, each of the one or more receiving receptacles being of a rectangular shape having four corners, at least one but not all of which is chamfered.

According to at least one embodiment, a carrier for receiving electronic modules is provided that allows the electronic modules to be surface-mounted in the correct orientation.

### BRIEF DESCRIPTION OF THE DRAWINGS

Other objects and further features of the present invention will be apparent from the following detailed description when read in conjunction with the accompanying drawings, in which:

FIGS. 1A and 1B are drawings illustrating an example of the appearance of a tape carrier;

FIG. 2 is an oblique perspective view of an example of the appearance of a tray carrier;

FIGS. 3A through 3G are front views of examples of the appearances of electronic modules for placement in a carrier;

FIGS. 4A and 4B are drawings illustrating examples in which an electronic module is placed in two different orientations;

FIGS. 5A through 5C are drawings illustrating examples in which an electronic module is placed in three different orientations; and

FIGS. 6A through 6D are drawings illustrating examples in which an electronic module is placed in four different orientations.

### DESCRIPTION OF EMBODIMENTS

In the following, embodiments of the present invention will be described with reference to the accompanying drawings.

### First Embodiment

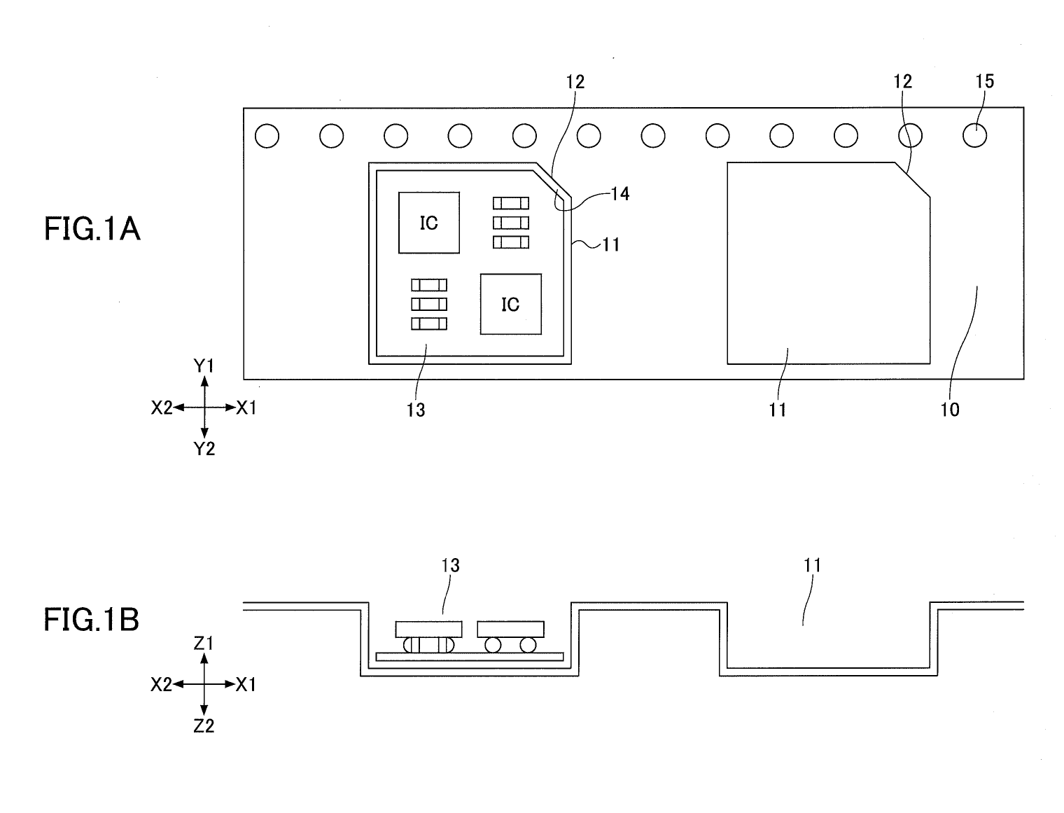

With reference to FIGS. 1A and 1B, a description will be given of a tape carrier according to a first embodiment of a carrier for receiving electronic modules (which will be hereinafter referred to as a “carrier”). FIGS. 1A and 1B are drawings illustrating an example of the appearance of a tape carrier 10. FIG. 1A is a plane view, and FIG. 1B is a lateral view.

In FIGS. 1A and 1B, the tape carrier 10 has receiving recesses 11 each of which is shaped to match the outline shape of an electronic module 13. A raw material used for the tape carrier may be conductive polystyrene, conductive polycarbonate, polyethylene terephthalate, or polypropylene, for example. The receiving recesses 11 are formed by an embossing process in which a metal mold is pressed against a heated raw material, for example.

Each of the receiving recesses 11 has a placement regulating part 12 that regulates the orientation in which the electronic module 13 is placed. The orientation subject to regulation is the orientation in which the electronic module 13 rotates horizontally in the X-Y plane defined in FIG. 1A. When the placement regulating part 12 does not coincide with a chamfered part 14 of the electronic module 13, the electronic module 13 cannot be properly placed in the receiving recess 11. In the present embodiment, one of the four corners of each receiving recess 11 in the X-Y plane, i.e., the corner situated in the X1-Y1 direction as viewed from the center of the recess, is defined as the placement regulating part 12. With this arrangement, the illustrated electronic module 13 can be properly placed only in one orientation.

The receiving recesses 11 have a pocket form separate from each other. A cover tape (not shown) may be adhered to the tape carrier 10 through heating adhesion or the like to seal off a selected receiving recess 11.

The tape carrier 10 is wound around a reel (not shown) and set in a chip mounting apparatus. The chip mounting apparatus pulls the tape carrier 10 from the reel, and positions the tape carrier 10 by use of holes 15 illustrated in FIG. 1A, followed by picking up an electronic module 13 from a receiving recess 11.

### Second Embodiment

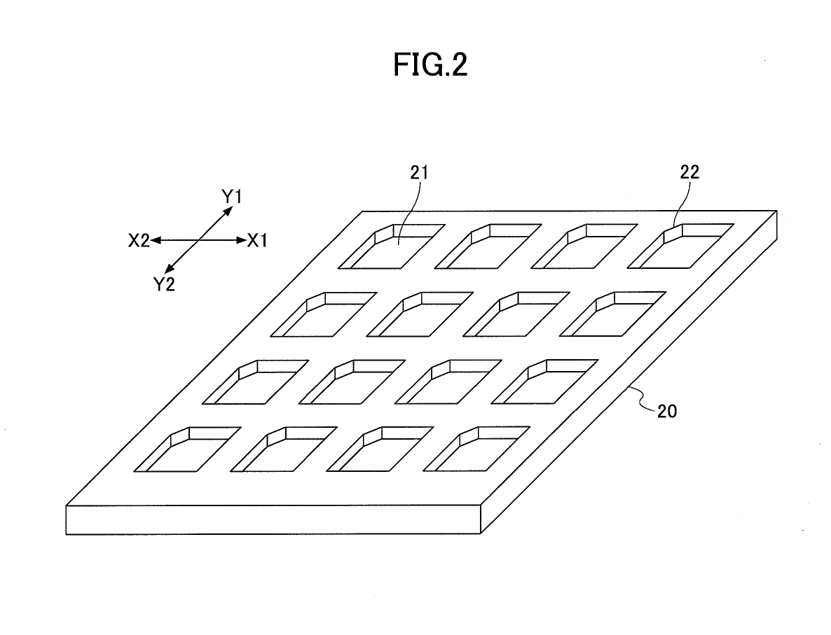

With reference to FIG. 2, a description will be given of a tray carrier according to a second embodiment of the carrier. FIG. 2 is an oblique perspective view of an example of the appearance of a tray carrier 20.

In FIG. 2, the tray carrier 20 has receiving recesses 21 that are arranged in a matrix of 4 rows and 4 columns in the X-Y plane. The matrix may be of any size, which may be 5 rows and 5 columns or 3 rows and 6 columns, for example. The material used for the tray carrier 20 may be conductive polystyrene, conductive polycarbonate, polyethylene terephthalate, or polypropylene, for example. The functions of the receiving recesses 21 in the tray carrier 20 are the same as the functions of the receiving recesses 11 in the tape carrier 10. In the present embodiment, a placement regulating part 22 of each receiving recess 21 is situated in the same direction, i.e., the X2-Y1 direction, as viewed from the center of the recess. Alternatively, the direction in which the placement regulating part is situated may vary from receiving recess to receiving recess to conform to the orientation in which each electronic module is mounted on an electronic substrate (not shown). In the present embodiment, further, the tray carrier 20 may accommodate electronic modules of the same type. Alternatively, a plurality of types of electronic modules to be mounted on an electronic substrate may be provided on the tray carrier 20. In the present embodiment, the receiving recesses 21 are formed to match the outline shapes (i.e., contour) of respective electronic modules. Even with the configuration in which a plurality of types of electronic modules are provided on the tray carrier 20, these electronic modules can be placed at correct positions in correct orientations.

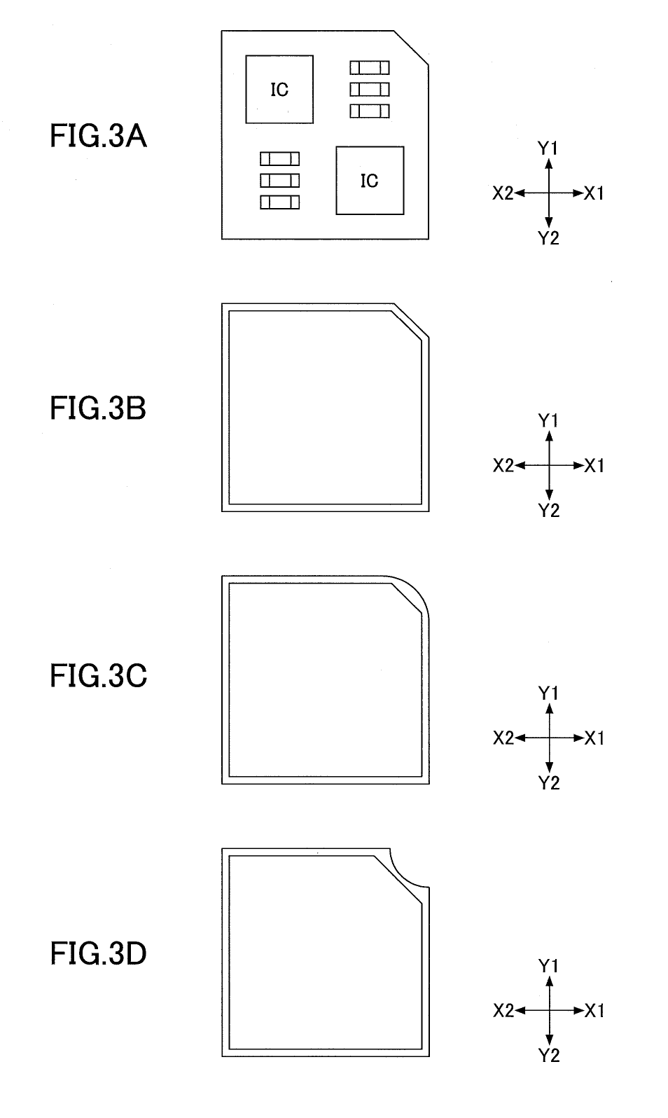

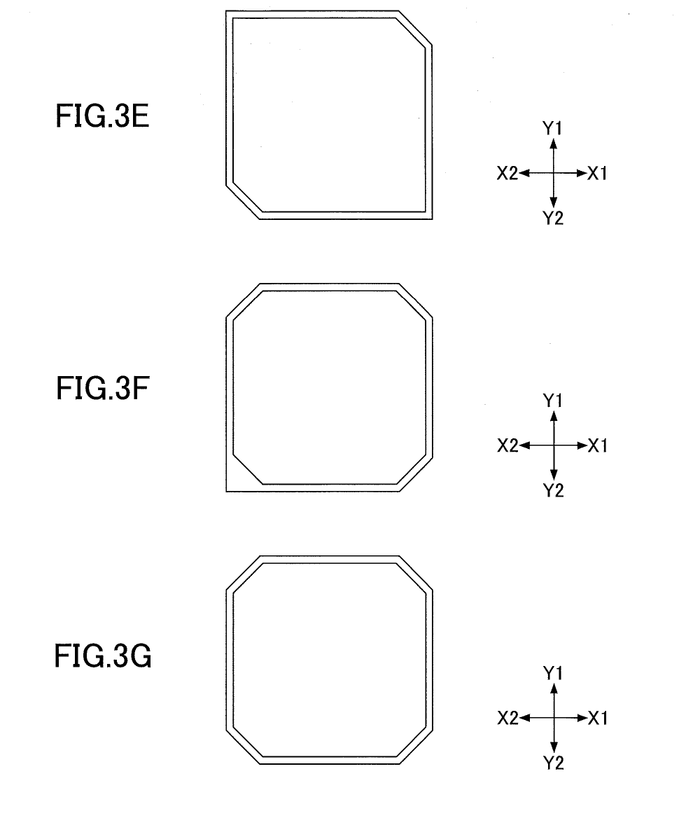

With reference to FIGS. 3A through 3G, a description will be given of electronic modules for placement in a carrier that are placed in the carrier according to the first embodiment or the second embodiment. FIGS. 3A through 3G are front views of examples of the appearances of electronic modules for placement in a carrier.

Some electronic modules can be mounted only in one orientation as described in connection with FIGS. 1A and 1B because of the locations of electrodes or the like. In such a case, the orientation in which an electronic module is placed is regulated by a receiving recess 21 that has a placement regulating part 22 for allowing placement in only one orientation. Some electronic modules may be properly mounted even when the orientation upon mounting is rotated 180 degrees in the X-Y plane illustrated in FIG. 1. Some other electronic modules may be properly mounted even when they are rotated 90 degrees clockwise or counterclockwise or rotated 180 degrees.

FIGS. 3A through 3D illustrate electronic modules that are properly mountable only in one orientation.

FIG. 3A illustrates a case in which one corner of an electronic module in the X1-Y1 direction is chamfered. The outline shape of an electronic module is formed to match (i.e., conform to) the shape of a receiving recess having a placement regulating part as described in connection with FIGS. 1A and 1B or FIG. 2. The chamfered shape ensures that the electronic module illustrated in FIG. 3A be placed only in one orientation in a receiving recess of the carrier described in connection with FIGS. 1A and 1B or FIG. 2.

FIG. 3B illustrates a shield case that is chamfered to have the same outline shape as the electronic module illustrated in FIG. 3A. Since the outline shape of the shield case is the same, the regulating effect regarding its orientation in a receiving recess is the same as or similar to the electronic module illustrated in FIG. 3A. The orientation of an electronic module to which a shield case is attached is difficult to check based on the arrangement of electronic components because these electronic components are covered by the shield case. When a system performs image analysis on video images taken by a TV camera to check the orientation of such an electronic module based on the arrangement of electronic components, an erroneous check result may be produced. The provision of a chamfered part to the shield case makes it easier to check the orientation from the appearance thereof even though the shield case is attached.

FIGS. 3C and 3D illustrate alternative embodiments in which the shape of a chamfered part is modified from the shape illustrated in FIG. 3B. As illustrated in FIGS. 3C and 3D, the shape of a chamfered part may be curved rather than being straight.

FIGS. 3E through 3G illustrate electronic modules that are mountable in a plurality of orientations. Some electronic modules may be mountable in a plurality of orientations because of the symmetric arrangement of terminals with respect to the center of the electronic modules, for example. FIG. 3E illustrates an example of an electronic module that is mountable in two orientations, i.e., mountable in a first orientation and also mountable in a second orientation upon being rotated 180 degrees in the X-Y plane relative to the first orientation. FIG. 3F illustrates an example of an electronic module that is mountable in three orientations in the X-Y plane. FIG. 3G illustrates an example of an electronic module that is mountable in four orientations in the X-Y plane. A description will be given of examples in which the shield cases illustrated in FIGS. 3E through 3G are placed in a receiving recess illustrated in FIGS. 1A and 1B or FIG. 2.

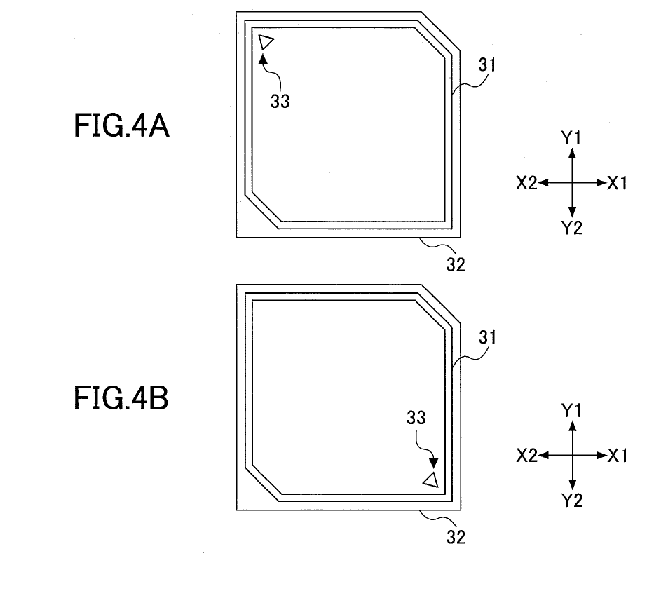

FIGS. 4A and 4B illustrate examples in which the electronic module of FIG. 3E is placed in two different orientations. In FIG. 4A and FIG. 4B, an electronic module 31 of FIG. 3E placed in a receiving recess 32 is rotated 180 degrees in the X-Y plane relative to each other as illustrated by an imaginary mark 33 for showing an orientation. When the placement regulating part 12 or 22 is provided at one corner of a square receiving recess as illustrated in FIG. 1A or FIG. 2, the electronic module of FIG. 3E can be placed in the two orientations as illustrated in FIGS. 4A and 4B. In this manner, the combination of the electronic module of FIG. 3E and the carrier of FIGS. 1A and 1B or FIG. 2 allows the electronic module to be correctly mounted in two mountable orientations.

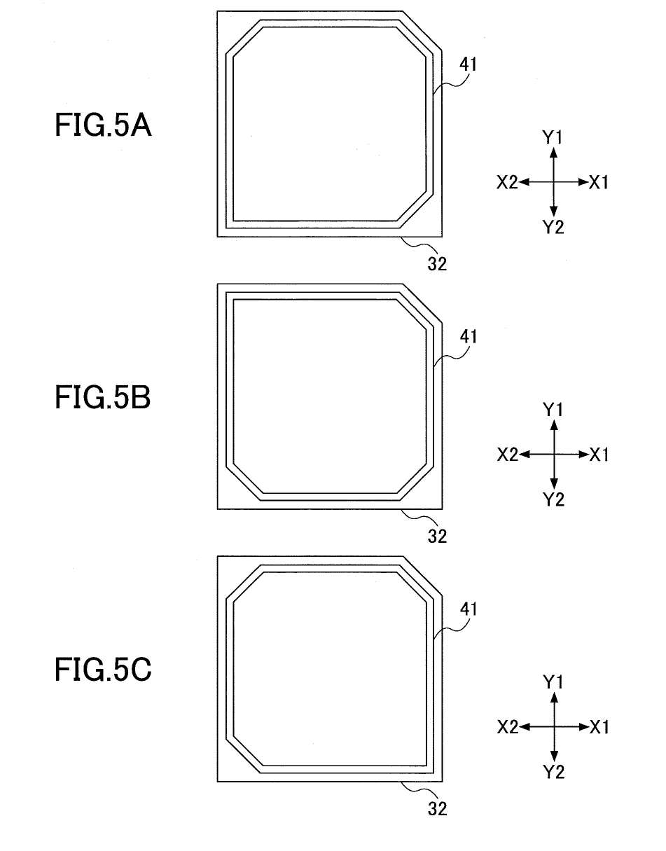

FIGS. 5A through 5C illustrate examples in which the electronic module of FIG. 3F is placed in three different orientations. In FIG. 5B and FIG. 5C, an electronic module 41 having an orientation illustrated in FIG. 5A is rotated 90 degrees clockwise and counterclockwise, respectively, to be placed in the receiving recess 32. When the placement regulating part 12 or 22 is provided at one corner of a square receiving recess as illustrated in FIG. 1A or FIG. 2, the electronic module of FIG. 3F can be placed in the three orientations as illustrated in FIGS. 5A through 5C. In this manner, the combination of the electronic module of FIG. 3F and the carrier of FIGS. 1A and 1B or FIG. 2 allows the electronic module to be correctly mounted in three mountable orientations.

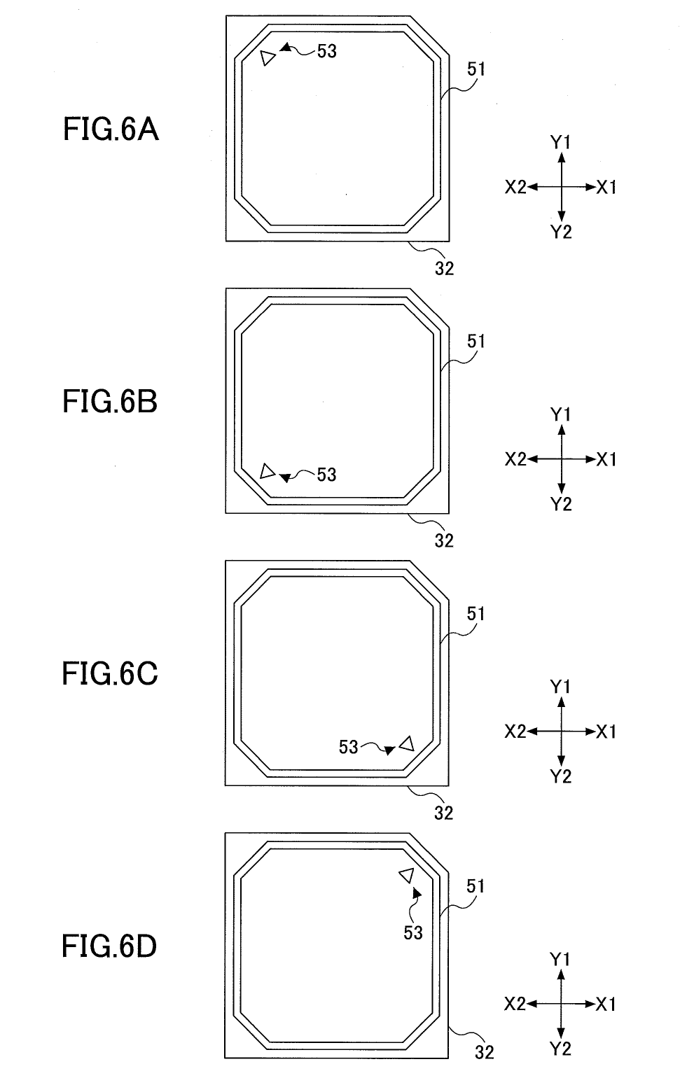

FIGS. 6A through 6D illustrate examples in which the electronic module of FIG. 3G is placed in four different orientations. In FIG. 6B through FIG. 6D, an electronic module 51 having an orientation illustrated in FIG. 6A is successively rotated 90 degrees to be placed in the receiving recess 32. When the placement regulating part 12 or 22 is provided at one corner of a square receiving recess as illustrated in FIG. 1A or FIG. 2, the electronic module of FIG. 3G can be placed in the four orientations as illustrated in FIGS. 6A through 6D. In this manner, the combination of the electronic module of FIG. 3G and the carrier of FIGS. 1A and 1B or FIG. 2 allows the electronic module to be correctly mounted in four mountable orientations.

The present embodiment has been described with reference to a case in which the placement regulating part is provided at one corner of a square receiving recess as illustrated in FIG. 1A or FIG. 2. When placement regulating parts are provided at two corners of a square receiving recess, for example, such placement regulating parts cause placement to be regulated according to their arrangement. A receiving recesses may be of an oblong rectangular shape, with the placement regulating part being provided at one corner thereof.

The present embodiment has been described with reference to a case in which a chip mounting apparatus performs automatic surface mounting. Even without the use of a chip mounting apparatus, the use of a disclosed electronic module makes it easier to make a visual determination of the orientation of the electronic module.

Further, the present invention is not limited to these embodiments, but various variations and modifications may be made without departing from the scope of the present invention.

For example, each of the carriers of the disclosed embodiments has been described as having receiving recesses. This is not a limiting example. The carrier may have only one recess. Further, the carrier may have one or more receiving receptacles, each of which is of a rectangular shape having four corners, at least one but not all of which is chamfered. The receiving receptacles may have borders thereof defined by walls, which regulate a position and orientation of an electronic module placed in a corresponding one of the receiving receptacles. Such walls may be erected and stand on the surface of the carrier. An electronic module is placed in a space surrounded by the walls. Such space has functions similar to the recess as described above. Alternatively, such receptacles may be recesses formed in the carrier.

The present application is based on Japanese priority application No. 2013-007848 filed on Jan. 18, 2013, with the Japanese Patent Office, the entire contents of which are hereby incorporated by reference.

What is claimed is:

1. A carrier for receiving one or more electronic modules, comprising a carrier member having one or more receiving receptacles, each of the one or more receiving receptacles being shaped to match an outline shape of an electronic module having at least one corner thereof chamfered.

2. The carrier as claimed in claim 1, wherein the carrier member is a tape or tray.

3. The carrier as claimed in claim 1, wherein the receiving receptacles are formed as recesses separate from each other.

4. The carrier as claimed in claim 1, further comprising a plurality of said electronic modules which are placed in the receiving receptacles.

5. An electronic module of a rectangular shape having four corners, at least one but not all of which is chamfered.

6. The electronic module as claimed in claim 5, wherein the at least one but not all of the four corners is a single corner.

7. A carrier for receiving electronic modules, comprising a carrier member having receiving receptacles, each of the receiving receptacles being of a rectangular shape having four corners, a single corner of which is chamfered.

8. The carrier as claimed in claim 7, wherein each of the receiving receptacles is a recess formed in the carrier member.
